(19) United States
(12) Patent Application Publication
(10) Pub. No.: US 2003/0191993 A1
(43) Pub. Date: Oct. 9, 2003

(54) Semiconductor device for memory test with changing address information

(76) Inventor: Takeshi Miwa, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/235,638

(22) Filed: Sep. 6, 2002

(30) Foreign Application Priority Data
Apr. 8, 2002 (JP) 2002-105421

(51) Int. Cl. G11C 29/00

(52) U.S. Cl. 714/718

(57) ABSTRACT

A semiconductor device for memory test with changing address information that writes and reads data to and from a memory array in accordance with address information includes an address converting circuit that makes a predetermined conversion of a part or the whole of address information in accordance with a control signal for a test to generate new address information. In the address converting circuit, the memory array is divided into a test program region and a memory region to be tested in accordance with a control signal for the test. For example, the address converting circuit interchanges a predetermined number of address bits of a line of bits constituting the address information with each other to generate new address information.

### BACKGROUND OF THE INVENTION

1. Field of the Invention

The present invention relates to a semiconductor device for memory test with changing address information provided with an address decoder and an internal memory having a function for producing the data of a memory array region by the address decoder and, in particular, to a semiconductor device for memory test with changing address information in which the memory array region of one internal memory is divided into independent regions that do not affect each other and in which the self-test of the internal memory itself is conducted.

2. Description of the Related Art

In general, a semiconductor memory device is formed on the same substrate along with a CPU and the like or is formed as one chip along with a CPU and the like. When the performance test of the semiconductor memory device is conducted, the performance test is conducted by the use of a tester.

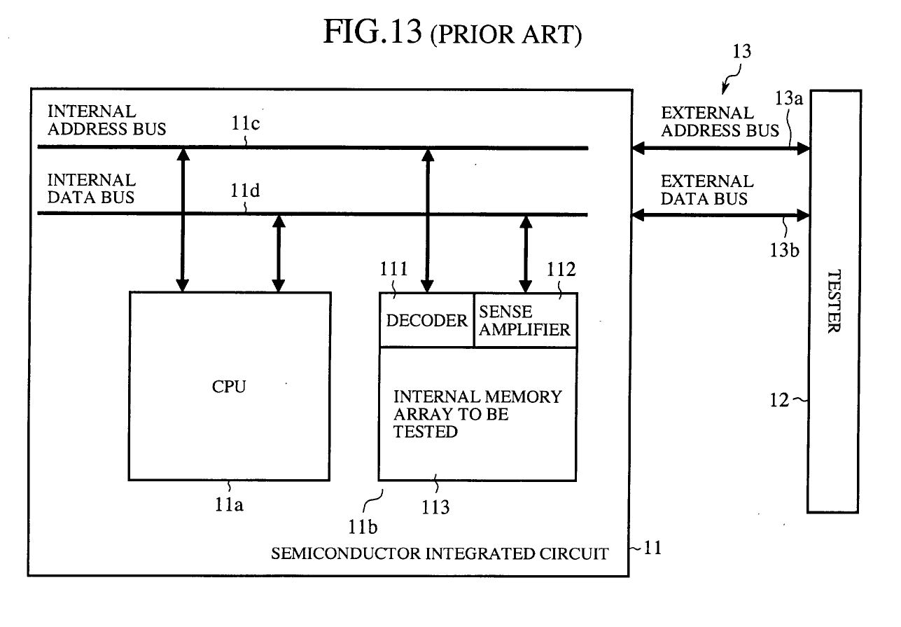

FIG. 13 is a block diagram to show one example of a semiconductor integrated circuit in the related art with a tester. In FIG. 13, a reference character 11 denotes a semiconductor integrated circuit that has an internal memory 11b as a semiconductor memory device; a reference character 11a denotes a CPU mounted in the semiconductor integrated circuit 11; a reference character 11b denotes the internal memory that has a decoder 111, a sense amplifier 112, and a memory array 113; reference characters 11c and 11d denote an internal address bus and an internal data bus that are mounted in the semiconductor integrated circuit 11; a reference character 12 denotes a tester used for testing the internal memory 11b; a reference character 13 denotes an external bus that has an external address bus 13a and an external data bus 13b, wherein the external address bus 13a and the external data bus 13b are the external address bus and the external data bus that connect the semiconductor integrated circuit 11 to the tester 12, respectively; a reference character 111 denotes a decoder that decodes a specified address and specifies the specified address of the memory array 113; a reference character 112 denotes a sense amplifier that outputs the data of the specified address to the internal data bus lid; and a reference character 113 denotes a memory array.

Next, the operation of the semiconductor integrated circuit will be described.

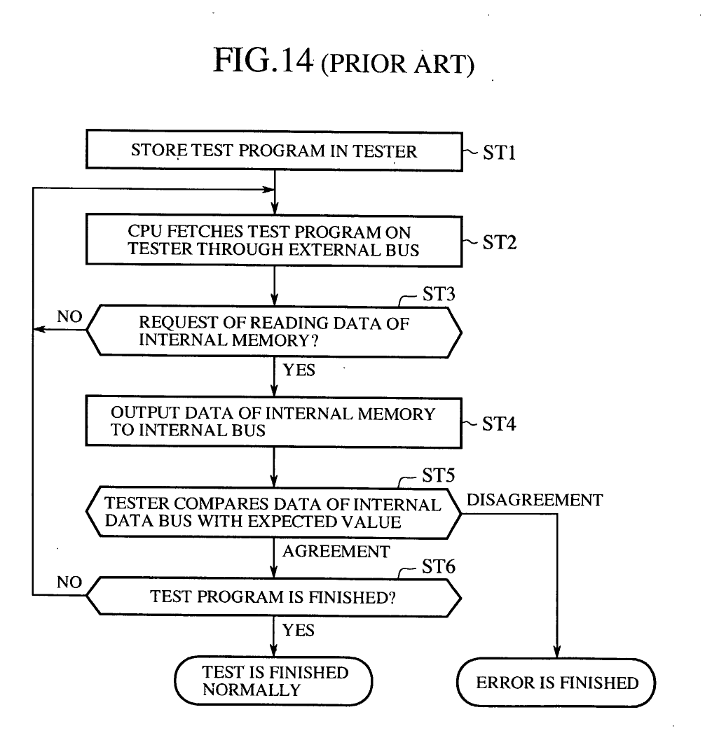

FIG. 14 is a flow chart describing the test of the internal memory in the semiconductor integrated circuit in FIG. 13 and a test operation will be described with reference to this drawing.

First, a test program is stored in the tester 12 (step ST1). Then, the CPU 11a fetches an instruction code of the test program on the tester 12 via the external bus 13 (step ST2). If the instruction code fetched is a data read request for the internal memory 11b (step ST3), the CPU 11a reads data from the internal memory 11b in accordance with the address received via the external address bus 13a and the internal address bus 11c and outputs the data to the internal data bus 11d (step ST4). The data on the internal data bus 11d is given to the tester 12 as output data via the external data bus 13b. Here, if the instruction code fetched is not a data test instruction in the step ST3, the program is returned to the step ST2.

Then, the tester 12 compares an expected value that is set in advance with the output data described above (step ST5). If the expected value does not agree with the output data, it is judged an error and the test is finished. If the expected value agrees with the output data, it is judged whether or not all of the test programs are finished (step ST6). If all of the test programs are finished, the test is finished. On the other hand, if all of the test programs are not finished, the program is returned to the step ST2 and the test is continued (the CPU 11a again fetches the instruction code of the test program).

By the way, in recent years, the semiconductor memory device has been increased in speed and capacity as a transistor has been patterned more finely. Further, as a progress has been made in increasing the speed and capacity of the semiconductor memory device, it has become difficult to test the performance of the semiconductor memory device by the use of an ordinary tester (low-cost and low-speed tester). Further, even if a high-speed tester is used, when the data is compared with the expected value by the use of the external bus, as described above, it is difficult to conduct the performance test of the semiconductor memory device (internal memory 11b) because of the performance capability of the external bus. In addition, with the increasing capacity of the semiconductor memory device, the test vector of the test program is increased in size and the time required to make the test vector like this can not be neglected.

In order to solve such problems, in the related art, the so-called self-test is conducted in which a program is previously stored in the internal memory itself of the semiconductor memory device and in which a CPU is operated in accordance with the program to thereby conduct the performance test of the semiconductor memory device.

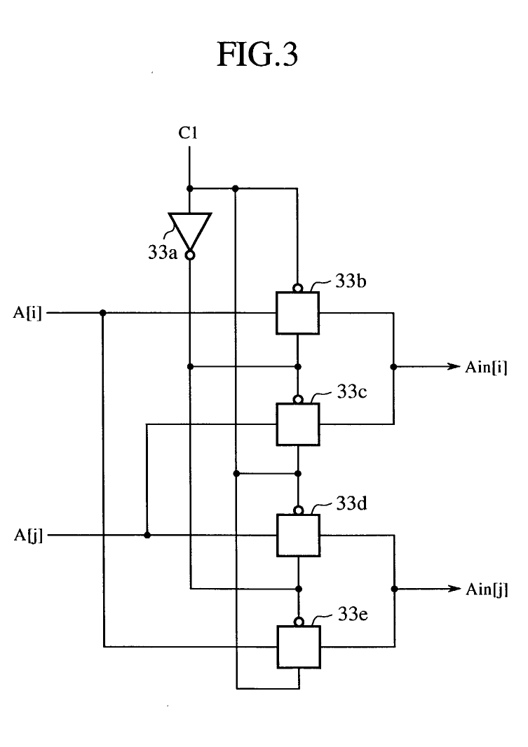

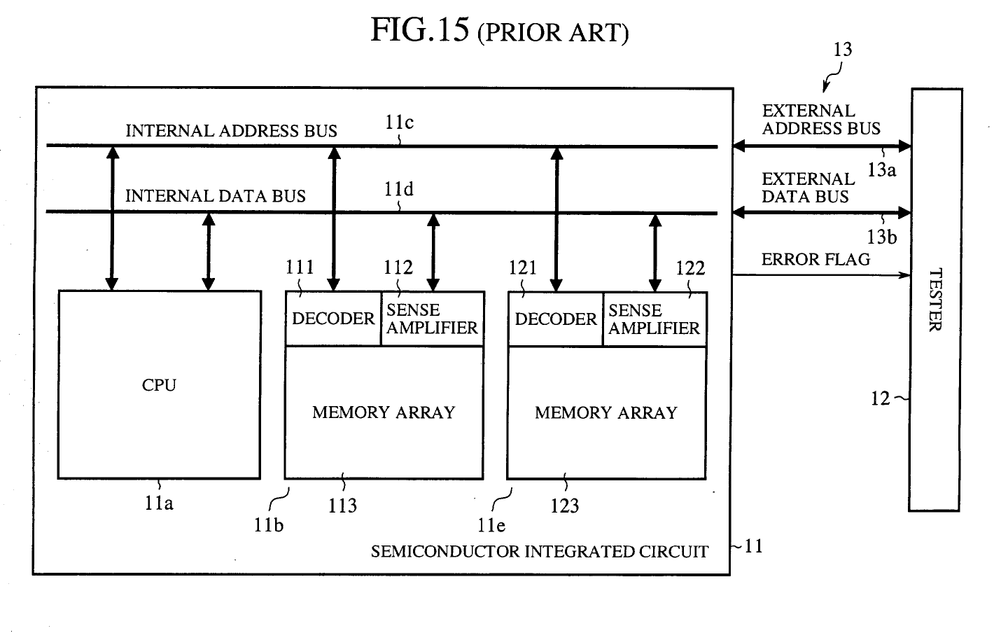

FIG. 15 is a block diagram to show another example of the semiconductor integrated circuit in the related art. In FIG. 15, a reference character 11e denotes an internal memory; a reference character 121 denotes a decoder; a reference character 122 denotes a sense amplifier that is provided separately from the internal memory 11b. Here, the same constituent parts as those in FIG. 3 are denoted by the same reference characters and their descriptions will be omitted.

Next, the operation of this semiconductor integrated circuit will be described.

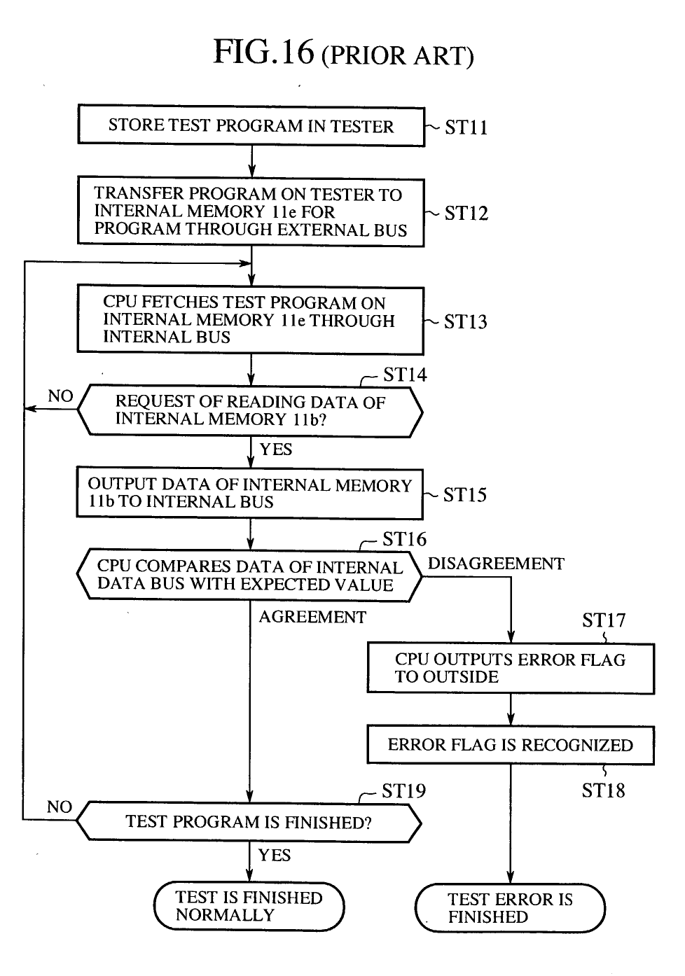

FIG. 16 is a flow chart describing the self-test of the internal memory of the semiconductor integrated circuit in FIG. 15, and the self-test will be described with reference to this drawing.

First, in order to conduct the self-test, the semiconductor integrated circuit 11 is provided with the internal memory 11e in addition to the internal memory 11b. The internal memory 11e has a decoder 121, a sense amplifier 122, and a memory array 123. Here, the internal memory 11b is an object to be tested and a test program is stored in the memory array 123 of the internal memory 11e.

When the internal memory 11b is tested, the test program is stored in the tester 12 (step ST11). Then, the test program on the tester 12 is transferred to the internal memory 11e via an internal address bus 11c and an internal data bus 11d at the operable seed of the external bus 13 (step ST12). A CPU 11a fetches the instruction code of the test program stored in the internal memory 11e via the internal bus (step ST13).

If the instruction code fetched is the data test instruction of the internal memory 11b (step ST14), the CPU 11a reads data from the internal memory 11b in accordance with the data test instruction and outputs the data to the internal data bus 11d (step ST15). Here, if the instruction code fetched in the step ST14 is not the data test instruction, the program is returned to the step ST13.

The CPU 11a compares the data on the internal data bus lid with an expected value that is set in advance (step ST16). If the data does not agree with the expected value, the CPU 11a outputs an error flag to a signal line by the use of a port (input/output terminal) (step ST17). At this time, the error flag is outputted at the operable speed of the signal line. The tester 12 recognizes an error by the error flag (step ST18) and finishes the test (error finish).

On the other hand, if the data agrees with the expected value, the CPU 11a judges whether or not the all of the test programs are finished (step ST19). At this time, if the CPU 11a judges that all of the test programs are finished, the test is normally finished. If the all of the test programs are not finished, the program is returned to the step ST13 and the test is continued (the CPU 11a again fetches the instruction code of the test program).

Since the test of the semiconductor memory device in the related art is conducted in the manner described above, in the semiconductor integrated circuit such as a one-chip microcomputer, it is necessary to provide an internal memory for storing a test program separately in addition to an internal memory to be tested. For this reason, there is presented a problem that the size of the circuit is inevitably increased.

On the other hand, in order to decrease the size of the circuit, it is thought to adopt a self-test specification. However, when data is read from the internal memory while the instruction code stored in the internal memory is being fetched, in some cases, the read/write of the test program and the read/write of the data occur at the same time. For this reason, occasionally, the test program stored in the internal memory causes a malfunction such as an unintended rewrite or makes a bad effect on a read margin. Further, it is also thought that it is impossible to conduct the test of the internal memory, depending on the data array of the internal memory, that is, it is difficult to conduct the self-test in a normal state.

### SUMMARY OF THE INVENTION

The present invention has been made to solve the above-mentioned problems. It is the object of the present invention to provide a semiconductor device for memory test with changing address information which is provided with an address decoder and an internal memory having a function of getting the data of a memory array region by the address decoder and in which the memory array region is divided into regions, which are independent of and do not affect each other, by the one internal memory and a small number of hardware to conduct the self-test of the internal memory itself.

A semiconductor device for memory test with changing address information in accordance with the present invention includes a memory array into which data based on predetermined address information are written and read; and address converting means that makes a predetermined conversion of a part or the whole of the address information to convert the address information into new address information for specifying a desired region in the memory array.

Therefore, according to the present invention, it is possible to produce an effect of preventing a circuit size (the quantity of hardware) from increasing and conducting the self-test normally.

A semiconductor device for memory test with changing address information in accordance with the present invention includes a memory array into which data based on predetermined address information are written and read; and a plurality of blocks for a test each of which has: address converting means that operates according to an inputted control signal to make a predetermined conversion of a part or the whole of the address information to thereby convert the address information into new address information for specifying a desired region in the memory array; at least one register that stores the expected value of data in the memory array; and comparing means that compares data read from one region in the memory array specified by the new address information generated by the address converting means with the expected value read from the register and outputs the result of comparison.

Therefore, according to the present invention, it is possible to produce an effect of shortening a testing time and responding to a complicated test.

### BRIEF DESCRIPTION OF THE INVENTION

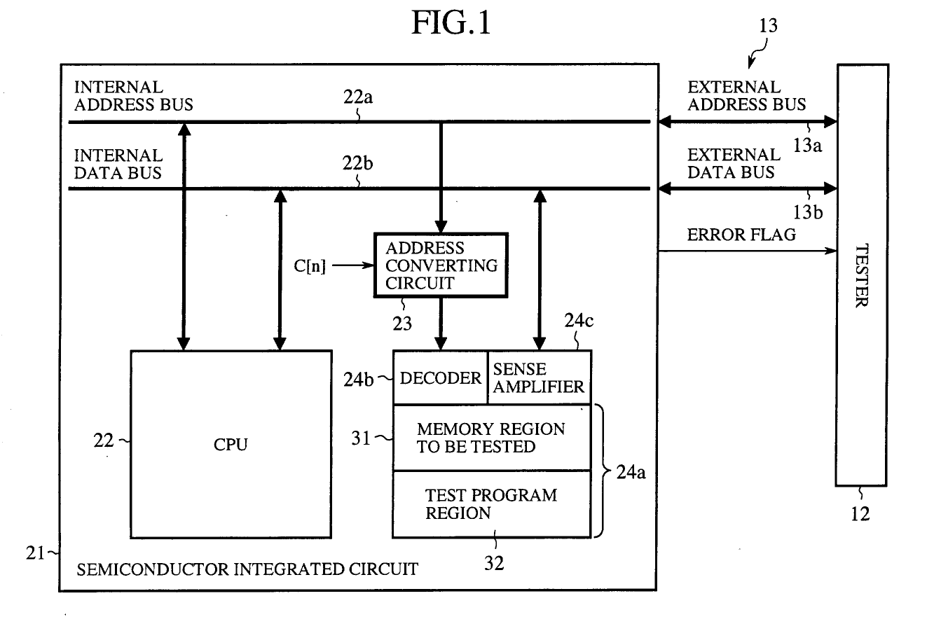

FIG. 1 is a block diagram to show the configuration of a semiconductor device for memory test with changing address information in accordance with the preferred embodiment 1 of the present invention along with a tester.

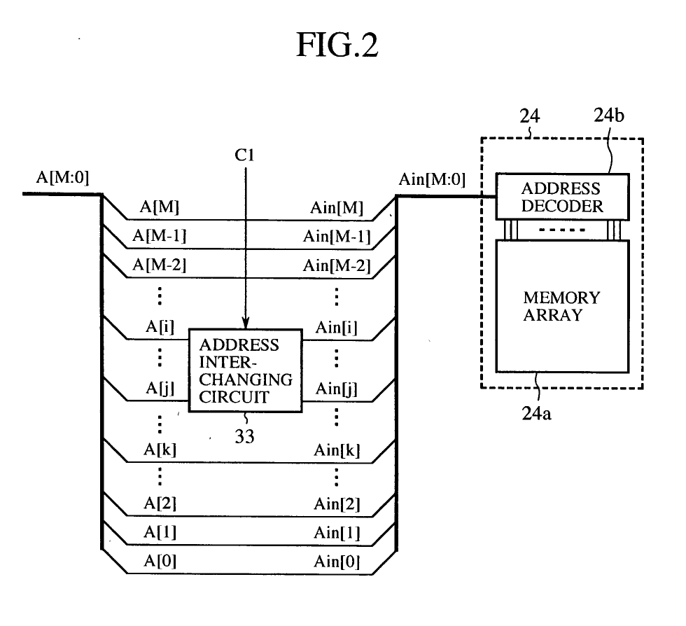

FIG. 2 is a diagram to describe one example of an address converting circuit shown in FIG. 1.

FIG. 3 is a block diagram to show one example of an address interchanging circuit shown in FIG. 1.

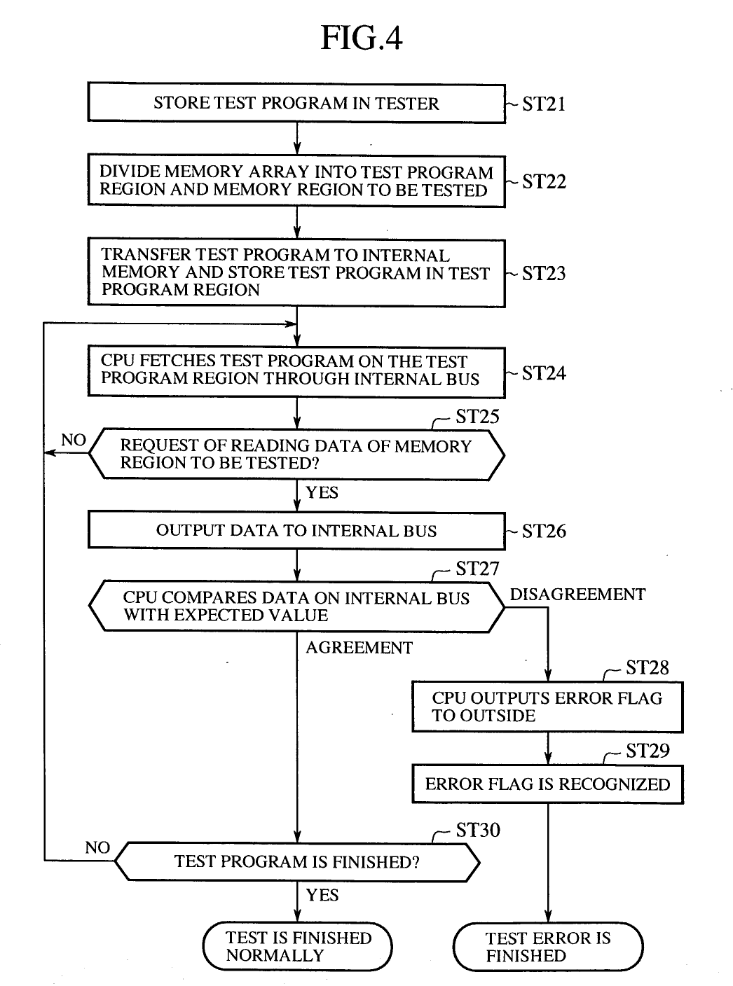

FIG. 4 is a flow chart to describe the self-test of an internal memory in the semiconductor device shown in FIG. 1.

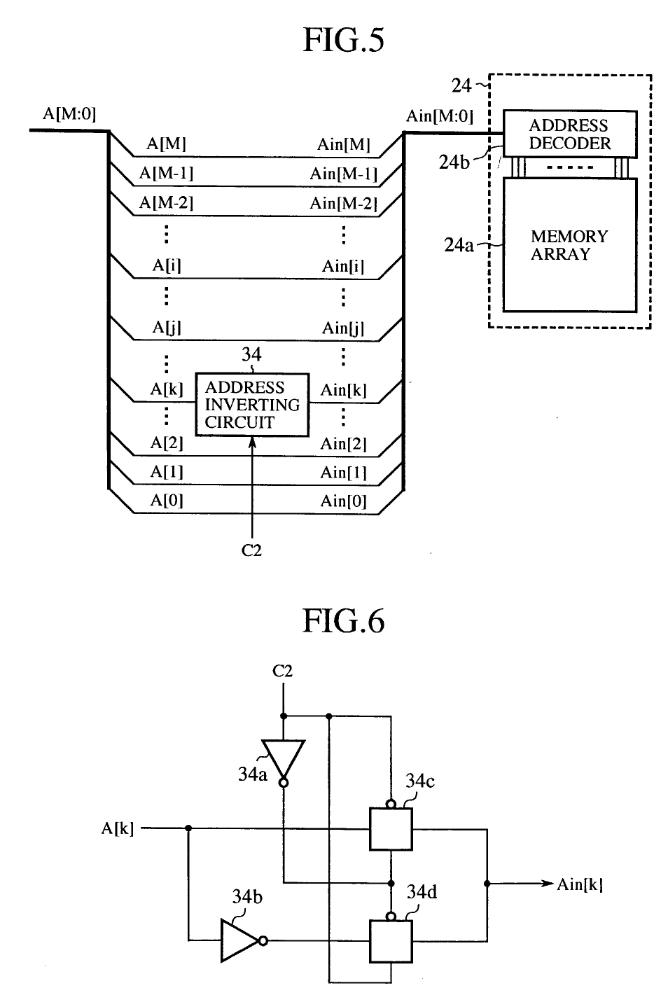

FIG. 5 is a diagram to describe another example of an address converting circuit shown in FIG. 1.

FIG. 6 is a block diagram to show one example of an address inverting circuit shown in FIG. 1.

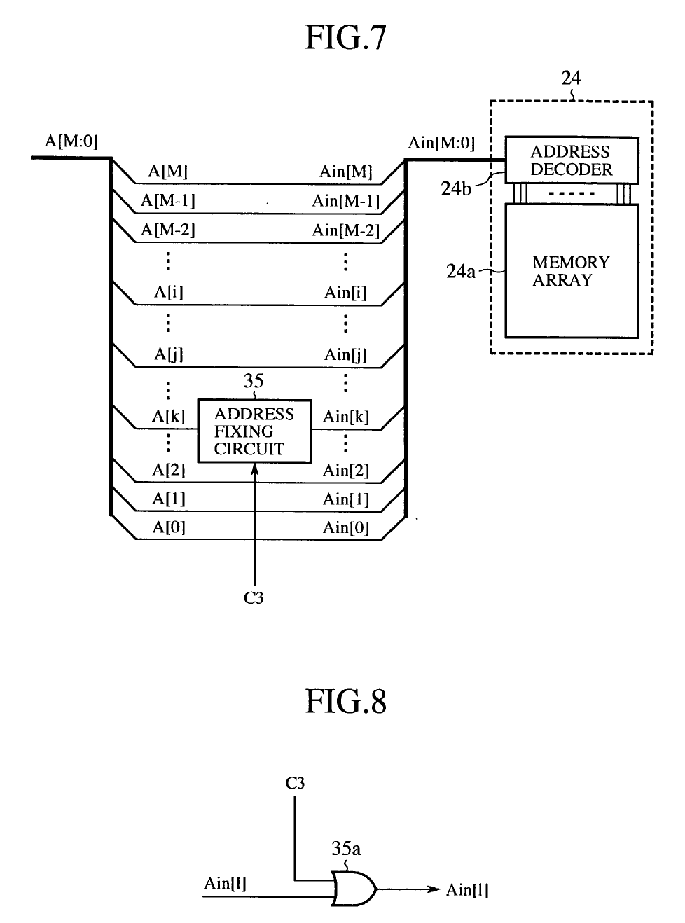

FIG. 7 is a diagram to describe still another example of an address converting circuit shown in FIG. 1.

FIG. 8 is a diagram to show an example of configuration of the address fixing circuit shown in FIG. 7.

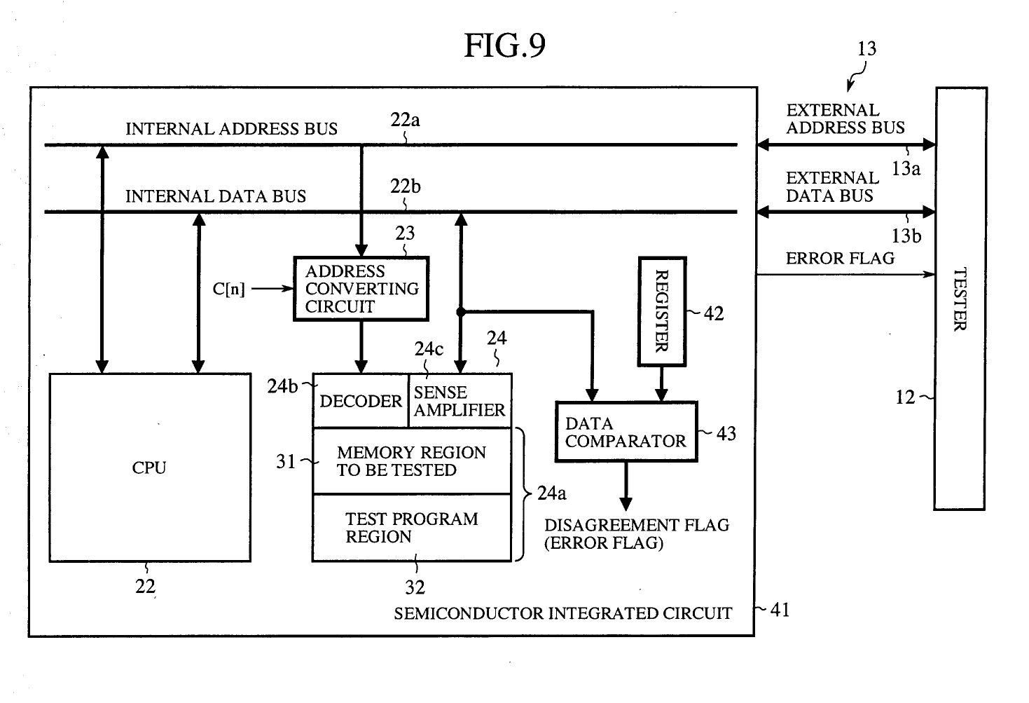

FIG. 9 is a block diagram to show the configuration of a semiconductor device in accordance with the preferred embodiment 2 of the present invention along with a tester.

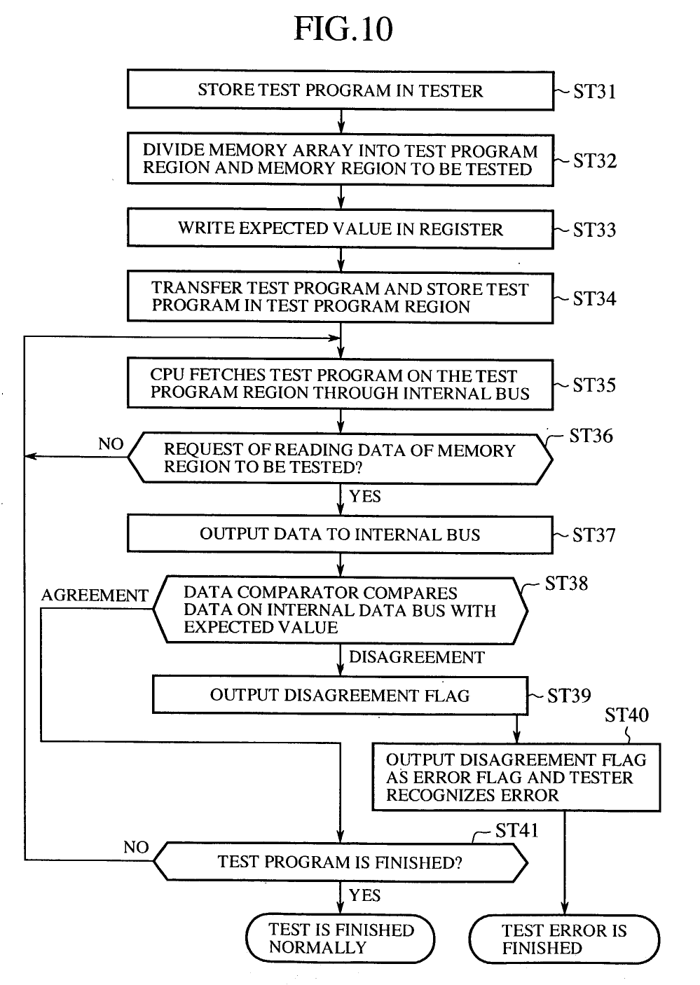

FIG. 10 is a flow chart to describe the self-test of an internal memory in a semiconductor device shown in FIG. 9.

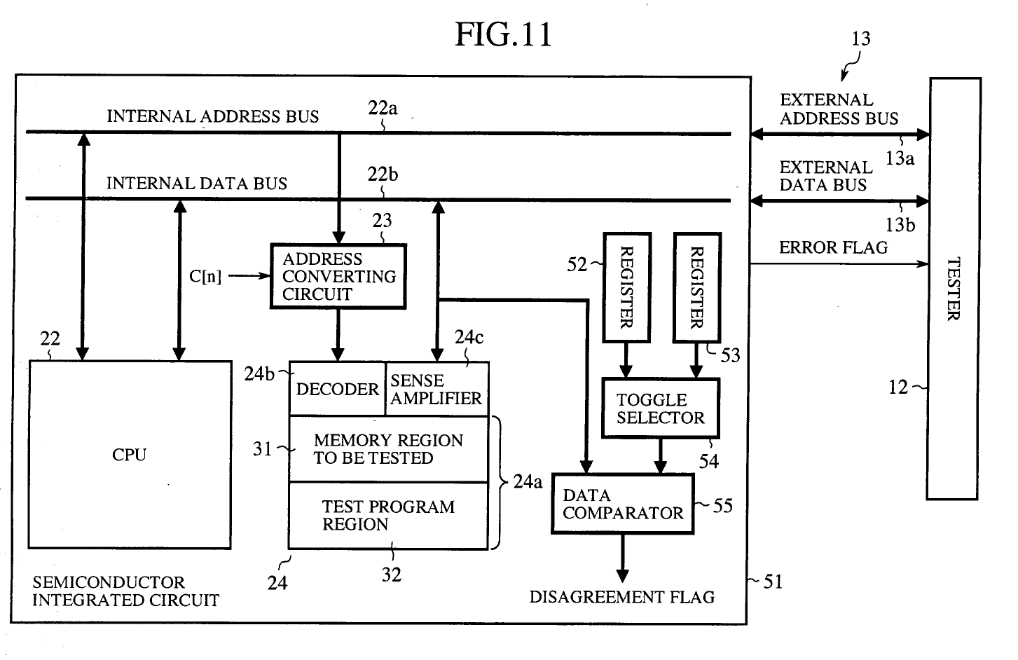

FIG. 11 is a block diagram to show the configuration of a semiconductor device in accordance with the preferred embodiment 3 of the present invention along with a tester.

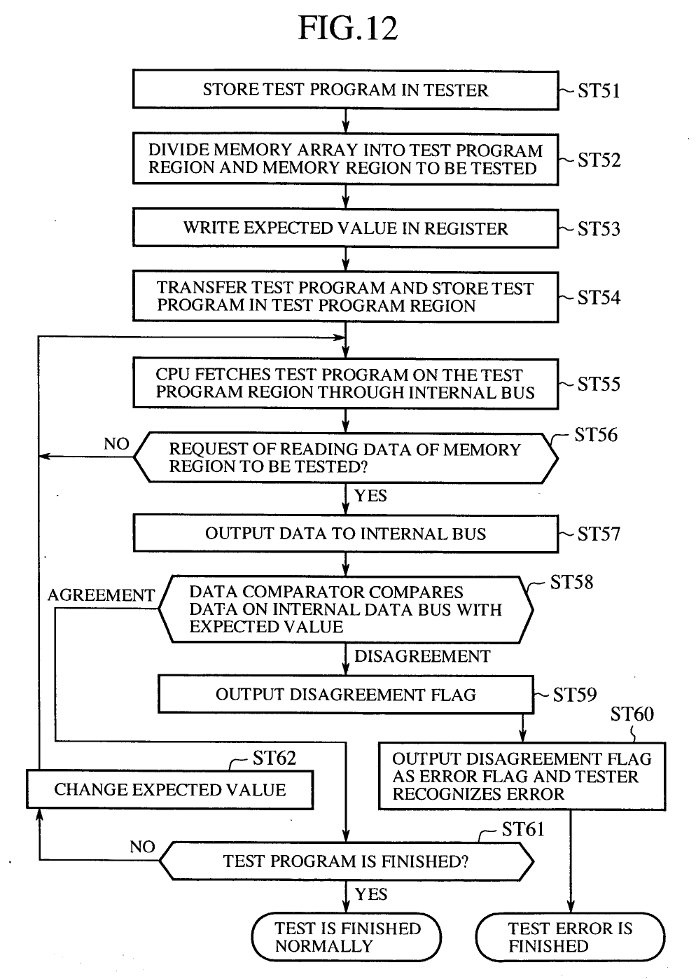

FIG. 12 is a flow chart to describe the self-test of an internal memory in a semiconductor device shown in FIG. 11.

FIG. 13 is a block diagram to show one example of a semiconductor device in the related art along with a tester.

FIG. 14 is a flow chart to describe the self-test of an internal memory in a semiconductor device shown in FIG. 13.

FIG. 15 is a block diagram to show another example of a semiconductor device in the related art along with a tester.

FIG. 16 is a flow chart to describe the self-test of an internal memory in a semiconductor device shown in FIG. 15.

### DESCRIPTION OF THE PREFERRED EMBODIMENTS

The preferred embodiments of the present invention will be hereinafter described.

Preferred Embodiment 1

FIG. 1 is a block diagram to show the configuration of a semiconductor device in accordance with the present invention of the present invention along with a tester. In FIG. 1, a reference character 21 denotes a semiconductor device; a reference character 22 denotes a CPU; a reference character 23 denotes an address converting circuit (address converting means); and a reference character 24 denotes an internal memory that is a semiconductor memory device. The CPU 22 is connected to an internal address bus 22a and an internal data bus 22b. The internal memory 24 is connected to the internal data bus 22b and, via the address converting circuit 23, the internal address bus 22a. Here, the internal memory 24 has a memory array 24a, an address decoder (decoder) 24b, and a sense amplifier 24c. The memory array 24a is divided into a memory region to be tested (data region: the second region) 31 and a test program region 32. The address converting circuit 23, as will be described later, selects the memory region to be tested 31 or the test program region 32 in accordance with a control signal for a test C[n] (where n is an integer not smaller than 1).

FIG. 2 is a diagram to show one example of an address converting circuit in FIG. 1. In FIG. 2, a reference character 33 denotes an address interchanging circuit (address converting means) that outputs an address in which two arbitrary bits of the internal address bus 22a of M bits interchange with each other to the address decoder 24b. A reference character A[M:0] designates the address of M (where m is an integer not smaller than 1) bits of the internal address bus 22a. A reference character A in [M:0] designates the address of an address bus (hereinafter referred to as an internal memory address) given to the internal memory 24 that is the semiconductor memory device. Here, the sense amplifier 24c is not shown in FIG. 2.

As shown in FIG. 2, the address A [M:0] has address bits A[M] to A[0]. Two arbitrary address bits A[i] and A[j] of these address bits A[M] to A[0] are given to the address interchanging circuit 33. Further, the address Ain[M:0] of the internal memory address bus has address bits (hereinafter referred to as an internal address bit) Ain[M] to Ain[0]. The values of the other address bits except for the above-mentioned address bits A[i] and A[j] are given to the address decoder 24b as the values of the internal address bits. On the other hand, for the address bits A[i] and A[j], the values of the address bits A[i] and A[j] are interchanged with each other by the address interchanging circuit 33 and the interchanged internal address bits Ain[i] and Ain[j] are given to the address decoder 24b.

FIG. 3 is a block diagram to show the example of configuration of the address interchanging circuit in FIG. 2. In FIG. 3, the address interchanging circuit 33 has an inverter 33a and transmission gates 33b to 33e. Here, when a low-level (L level) control signal for a test C1 is inputted (that is, in a state where the control signal for a test is not given), the transmission gates 33b and 33d are turned on, whereas the transmission gates 33c and 33e are turned off. As a result, the value of the address bit A[i] is given as the internal address bit Ain[i] to the address decoder 24b. Further, similarly, the address bit A[j] is given as the internal address bit Ain[j] to the address decoder 24b. In other words, the address bit A[i] is equal in logic to the internal address bit Ain[i] and the address bit A[j] is equal in logic to the internal address bit Ain[j]. In this manner, the internal address Ain[M:0] of M bits that is equal in logic to the address A[M:0] of M bits is given to the address decoder 24b.

On the other hand, if the control signal for a test C1 is a high level (H level) (that is, in a state where the control signal for a test is given), the transmission gates 33c and 33e are turned on, whereas the transmission gates 33b and 33d are turned off. As a result, the address bit A[i] is given to the address decoder 24b as the internal address bit Ain[j]. Further, similarly, the address bit A[j] is given to the address decoder 24b as the internal address bit Ain[i]. In other words, the address bit A[i] becomes equal in logic to the internal address bit Ain[j] and the address bit A[j] becomes equal in logic to the internal address bit Ain[i]. That is to say, an address in which the values of the address bits A[i] and A[j] of the address A[M:0] of M bits are interchanged with each other is given to the address decoder 24b as the internal address Ain[M:0].

With this address interchanging circuit, even if the address A[M:0] is the same, it is possible to change (convert) the internal address Ain [M:0] in accordance with the control signal for a test C1 and thus to make an access to a different memory region of the memory array 24a.

Next, the operation of the semiconductor device will be described.

FIG. 4 is a flow chart of the self-test of the internal memory in the semiconductor device shown in FIG. 1. The self-test in the present invention will be described with reference to FIG. 4.

First, the external buses 13 (the external address bus 13a and the external data bus 13b) are connected to the tester 12 and the port (input/output terminal) of the semiconductor device 21 is connected to the tester 12 by a signal line. Then, a test program is stored in the tester 12 (step ST21).

Here, a signal line that gives a control signal for a test C[n] (=C1, where n=1) to the address interchanging circuit 33 of the address converting circuit 23 is connected to the other port of the semiconductor device 21. The address interchanging circuit 33 outputs, with respect to one address of the internal address bus 22a, the address which is equal to an inputted value and the address in which the values of the predetermined 2 bits are interchanged with each other to the address decoder 24b in accordance with the control signal for a test C1. In this manner, the memory array 24a is divided into a memory region to be tested 31 and a test program region 32 (step ST22).

Next, the test program stored in the tester 12 is transferred to the internal memory 24 at the operable speed of the external bus 13 via the internal bus (internal address bus 22a and internal data bus 22b) and is stored in the test program region 32 (step ST23).

To be more specific, first, assuming that the control signal for a test C1 is an H level, the address interchanging circuit 33 gets the respective data constituting a test vector inputted thereto and interchanges two predetermined bits in the respective addresses corresponding to the respective data to convert them to addresses corresponding to the memory region to be tested 31. In this manner, the test vector is selectively stored in the memory region to be tested 31. Here, the address specified first by the test vector and the address interchanged are already known. In this manner, by specifying the address for storing the test program such that it does not overlap the address in the memory region to be tested 31, the test program is stored in the test program region 32 that is independent of and not affected by the memory region to be tested 31.

Then, the CPU 22 fetches the instruction code of the test program from the test program region 32 via the internal bus and executes the instruction (step ST24). At this time, if the instruction code fetched by the CPU 22 is a data read request from the memory region to be tested 31 (step ST25), the CPU 22 reads data from the memory region to be tested 31 and outputs the data to the internal data but 22b (step ST26). Here, in the step ST25, if the instruction code fetched by the CPU 22 is not the data read request from the memory region to be tested 31, the program is returned to the step ST24.

Next, the CPU 22 compares the data on the internal data bus 22b with an expected value that is set in advance (step ST27). If the data does not agree with the expected value, the CPU 22 outputs an error flag to the signal line by the use of the port (input/output terminal) (step ST28). Here, the error flag is outputted at the operable speed of the signal line. The tester 12 recognizes the error by the error flag (step ST29) and finishes the program as a test error.

On the other hand, if the data agrees with the expected value, the CPU 22 judges whether or not all of the test programs are finished (step ST30). At this time, if all of the test programs are finished, the CPU 22 judges that the test normally finished. If all of the test programs are not finished, the program is returned to the step ST24, the CPU 22 fetches the instruction code of the test program.

Next, another example of the address converting circuit 23 will be described.

FIG. 5 is a diagram to describe another example of the address converting circuit shown in FIG. 1. Here, for example, an address inverting circuit (address converting means) 34 is used as the address converting circuit 23. Here, the same constituent parts as those shown in FIG. 2 are denoted by the same reference characters. As shown in FIG. 5, one arbitrary address bit A[k] of the address bits A[M] to A[0] is given to the address inverting circuit 34. The other address bits except for the above-mentioned A[k] are given to the address decoder 24b as the internal address bits. On the other hand, the address bit A[k], as will be described later, is inverted by an address inverting circuit 34 and is given to the address decoder 24b as the internal address bit Ain[k].

FIG. 6 is a block diagram to show one example of the address inverting circuit shown in FIG. 5. In FIG. 5, the address inverting circuit 34 has inverters 34a, 34b and transmission gates 34c, 34d. If a control signal for a test C2 (here, n 2) is an L level, the transmission gate 34c is turned on and the transmission gate 34d is turned off. As a result, the address bit A[k] is given to the internal address decoder 24b as the internal address bit Ain[k]. In other words, the address bit A[k] is equal in logic to the internal address bit Ain[k]. In this manner, the internal address Ain[M:0] that is equal in logic to the address A[M:0] of M bits is given to the address decoder 24b.

On the other hand, if the control signal for a test C2 is an H level, the transmission gate 34d is turned on and the transmission gate 34c is turned off. As a result, an inverted address bit made by inverting the address bit A[k] by the inverter 34b is given to the address decoder 24b as the internal address bit Ain[k].

In this manner, even if the address A[M:0] is the same, it is possible to change (convert) the internal address Ain[M:0] in accordance with the control signal for a test C2 and thus to make an access to a different memory region of the memory array 24a. That is to say, it is possible to divide the memory array 24a into two regions (test program region and the memory region to be tested).

Next, still another example of the address converting circuit 23 will be described.

FIG. 7 is a diagram to describe still another example of the address converting circuit shown in FIG. 1. Here, for example, an address fixing circuit (address converting means) 35 is used as the address converting circuit 23. Here, the same constituent parts as those shown in FIG. 2 are denoted by the same reference characters. As shown in FIG. 7, one arbitrary address bit A[l] of the address bits A[M] to A[0] is given to the address fixing circuit 35. The other address bits except for the above-mentioned A[l] are given to the address decoder 24b as the internal address bits. On the other hand, the address bit A[l], as will be described later, is controlled by an address fixing circuit 35 and is given to the address decoder 24b as the internal address bit Ain[l].

FIG. 8 is a diagram to show the example of configuration of the address fixing circuit shown in FIG. 7. In FIG. 7, the address fixing circuit 35 has an OR circuit 35a. If a control signal for a test C3 (here, n=3) is an L level, the OR circuit 35a outputs the address bit A[l] as an internal address bit Ain[l]. In other words, the address bit A[l] is equal in logic to the internal address bit Ain[l]. In this manner, the internal address Ain [M:0] that is equal in logic to the address A[M:0] of M bits is given to the address decoder 24b.

On the other hand, if the control signal for a test C3 is an H level, the OR circuit 35a outputs the H level irrespective of the address bit A[l]. In other words, the internal address bit Ain[l] is fixed at the H level (for example, logic “1”). As a result, the internal address Ain [M:0] in which the internal address bit Ain [l] is logic “1” is given to the address decoder 24b.

In this manner, even if the address A[M:0] is the same, it is possible to change (convert) the internal address Ain[M:0] in accordance with the control signal for a test C3 and thus to make an access to a different memory region of the memory array 24a. That is to say, it is possible to divide the memory array 24a into two regions (test program region 32 and the memory region to be tested 31).

As described above, according to the present preferred embodiment 1, there is provided the address converting circuit 23 that divides the memory array region into the memory region to be tested 31 for storing the test data and the test program region 32 for storing the test program, so that it is possible to prevent an increase in a circuit size (quantity of hardware) and to conduct a self-test normally.

In this respect, while the example has been described in the preferred embodiment 1, in which two arbitrary address bits are converted, a plurality of arbitrary address bits may be converted. Further, if the value of the address after conversion can be specified to a predetermined value, the address converting circuit 23 is not limited to the converting operation described above.

Preferred Embodiment 2

FIG. 9 is a block diagram to show the configuration of a semiconductor device in accordance with the preferred embodiment 2 of the present invention along with a tester. Here, the same constituent parts as those shown in FIG. 1 will be denoted by the same reference characters. In FIG. 9, a reference character 41 denotes a semiconductor device and in addition to a CPU 22, an address converting circuit 23, and an internal memory 24, there are provided a register 42 and a data comparator (comparing means) 43. An expected value relating to data read from a memory region to be tested 31 is set in the register 42 (this expected value is set for each memory array 24a). Further, the data comparator 43 is connected to an internal address bus 22b and the register 42.

Next, the operation of the semiconductor device will be described.

FIG. 10 is a flow chart to describe the self-test of the internal memory of the semiconductor device shown in FIG. 9, and the self-test of the present preferred embodiment will be described with reference to FIG. 10.

First, the external bus 13 is connected to the tester 12 and the port (input/output terminal) of the semiconductor device 41 is connected to the tester 12 by a signal line. Then, a test program is stored in the tester 12 (step ST31). Then, a control signal for a test C[n] (where n is any one integer of from 1 to 3) is given to the address converting circuit 23 from the other port of the semiconductor device 41. In the address converting circuit 23, as is the case with the preferred embodiment 1 described above, the memory array 24a is divided into the test program region 32 and the memory region to be tested 31 in accordance with the control signal for a test C[n].

Next, an expected value relating to data read from the memory region to be tested 31 is set at a register 42 from the port of the semiconductor device 41 (step ST33: a signal line (route) when the expected value is set at the register 42 from the port is not shown in FIG. 9).

The test program stored in the tester 12 is transferred to the internal memory 24 at the operable speed of the external bus 13 via the internal bus and is stored in the test program region 32 (step ST34).

The CPU 22 fetches the instruction code of the test program stored in the test program region 32 via the internal bus and executes the instruction (step ST35). At this time, if the instruction code fetched is a data read request from the memory region to be tested 31 (step ST36), the CPU 22 reads data from the memory region to be tested 31 and outputs the data to the internal data bus 22b (step ST37). Here, if the instruction code is not the data read request from the memory region to be tested 31 in the step ST36, the program is returned to the step ST35.

The data comparator 43 compares data on the internal data bus 22b with the expected value set at the register 42 (step ST38). If the data does not agree with the expected value, the data comparator 43 outputs a disagreement flag (step ST39). This disagreement flag is outputted as an error flag from the port (input/output terminal) via the signal line. At this time, the error flag is outputted at the operable speed of the signal line. The tester 12 recognizes an error by the error flag (step ST40) and finishes the program as a test error.

On the other hand, if the data agrees with the expected value, the CPU 22 judges whether or not all of the test programs are finished (step ST41). At this time, if all of the test programs are finished, the test is normally finished. If all of the test programs are not finished, the program is returned to the step ST35 and the test is continued (the CPU 22 again fetches the instruction code of the test program).

As described above, according to the present preferred embodiment 2, the semiconductor device is provided with the register that stores the expected value and the data comparator that compares the data read by the test program with the expected value, so that it is not necessary for the CPU to compare the expected value with the date. As a result, when the same data is read, it is possible to conduct the test extremely easily. Here, when the data is read, if the expected vale is set again at the register, also in the case where data other than the same data is read, it is possible to conduct the test easily.

Preferred Embodiment 3

FIG. 11 is a block diagram to show the configuration of a semiconductor device in accordance with the preferred embodiment 3 of the present invention along with a tester. Here, the same constituent parts as those shown in FIG. 1 will be denoted by the same reference characters. In FIG. 11, a reference character 51 denotes a semiconductor device and in addition to a CPU 22, an address converting circuit 23, and an internal memory 24, there are provided a plurality of registers (in the example shown, two registers 52, 53), a toggle selector 54 and a data comparator 55. Expected values that are different from each other (expected values relating to data stored in a memory region to be tested) are set in the registers 52 and 53, respectively. Further, the data comparator 55 is connected to an internal address bus 22b and the registers 52, 53 via the toggle selector 54.

Next, the operation of the semiconductor device will be described.

FIG. 12 is a flow chart to describe the self-test of the internal memory of the semiconductor device shown in FIG. 11, and the self-test of the present preferred embodiment will be described with reference to FIG. 12.

First, the external bus 13 is connected to the tester 12 and the port (input/output terminal) of the semiconductor device 51 is connected to the tester 12 by a signal line. Then, a test program is stored in the tester 12 (step ST51). Then, a control signal for a test C[n] (where n is any one integer of from 1 to 3) is given to the address converting circuit 23 from the other port of the semiconductor device 51. In the address converting circuit 23, as is the case with the preferred embodiment 1 described above, the memory array 24a is divided 30 into the test program region 32 and the memory region to be tested 31 in accordance with the control signal for a test C[n] (step ST52). Next, expected values relating to the memory region to be tested 31 are set at the registers 52, 53 from the port of the semiconductor device 41 (step ST53). Here, in the example shown in FIG. 11 is not shown a signal line (route) when an expected value is set at the registers 52, 53 from the port. Further, the expected values set at the registers 52, 53 are referred to as the first expected value and the second expected value.

Next, the test program stored in the tester 12 is transferred to the internal memory 24 at the operable speed of the external bus 13 via the internal bus and is stored in the test program region 32 (step ST54). The CPU 22 fetches the instruction code of the test program stored in the test program region 32 via the internal bus and executes the instruction (step ST55). At this time, if the instruction code fetched is a data read request from the memory region to be tested 31 (step ST56), the CPU 22 reads data from the memory region to be tested 31 and outputs the data to the internal data bus 22b (step ST57). Here, if the instruction code is not the data read request from the memory region to be tested 31 in the step ST56, the program is returned to the step ST55.

At this time, the toggle selector 54 selects the first expected value set at the register 52 and gives the first expected value to the data comparator 55. The data comparator 55 compares data on the internal data bus 22b with the first expected value (step ST58). If the data does not agree with the first expected value, the data comparator 55 outputs a disagreement flag (step ST59). This disagreement flag is outputted as an error flag from the port (input/output terminal) via the signal line. At this time, the error flag is outputted at the operable speed of the signal line. In this manner, the tester 12 recognizes an error by the error flag (step ST60) and finishes the program as a test error.

On the other hand, if the data agrees with the first expected value, the CPU 22 judges whether or not all of the test programs are finished (step ST61). At this time, if all of the test programs are finished, the test is normally finished. If all of the test programs are not finished, the toggle selector 54 selects the second expected value set at the register 53 and gives the second expected value to the data comparator 55 (change of the expected value: step ST62). Then, the program is returned to the step ST55 and the test is continued (the CPU 22 again fetches the instruction code of the test program).

Incidentally, in the above-described embodiment has been described the example in which: two registers 52, 53 are provided; the first expected value and the second expected value are set in the registers 52, 53, respectively; and the toggle selector 54 outputs the first expected value and the second expected value selectively (sequentially). It is also recommended, however, that N (where N is an integer not smaller than 2) registers are provided and that the first to Nth expected values are stored in the N registered and that the toggle selector 54 outputs the first to Nth expected values selectively (sequentially) and that the data comparator 55 compares the data on the data bus with the expected values.

As described above, according to the present preferred embodiment 3, the semiconductor device is provided with the plurality of registers that store the different expected values, respectively, and the data comparator that compares the data read by the test program with the expected values, so that it is not necessary for the CPU to compare the expected values with the data. As a result, when the plurality of data are read in sequence, it is possible to conduct the test extremely easily.

In this respect, it is also recommended that the address converting circuit 23, the registers 42, 52, 53, and the data comparators 43, 55, which have been described above in the preferred embodiments 1 to 3, be constituted as one block for a test and that the test be conducted by a combination of the plurality of blocks. In this manner, it is possible to shorten a testing time and to respond to a complicated test.

What is claimed is:

1. A semiconductor device for memory test with changing address information comprising:
a memory array into which data based on a predetermined address information are written and read; and
address converting means that makes a predetermined conversion of a part or the whole of the address information to convert the address information into new address information for specifying a desired region in the memory array.

2. The semiconductor device as claimed in claim 1, wherein the address converting means interchanges a predetermined number of address bits of a line of bits constituting the address information with each other to generate new address information.

3. The semiconductor device as claimed in claim 1, wherein the address converting means inverts a predetermined number of address bits of a line of bits constituting the address information to generate new address information.

4. The semiconductor device as claimed in claim 1, wherein the address converting means fixes a predetermined number of address bits of a line of bits constituting the address information at logic value previously specified to generate new address information.

5. The semiconductor device as claimed in claim 1, further comprising:
at least one register that stores an expected value of data in the memory array; and
a comparing means that compares data read from one region in the memory array specified by the new address information generated by the address converting means with the expected value read from the register, and outputs the result of comparison.

6. A semiconductor device for memory test with changing address information comprising:
a memory array into which data based on a predetermined address information are written and read; and
a plurality of blocks for a test each of which has:
an address converting means that operates according to a respectively inputted control signal to make a predetermined conversion of a part or the whole of the address information to thereby convert the address information into new address information for specifying a desired region in the memory array;
at least one register that stores the expected value of data in the memory array; and
a comparing means that compares data read from one region in the memory array specified by-the new address information generated by the address converting means with the expected value read from the register and outputs the result of comparison.
